(19) United States
(12) Patent Application Publication
(10) Pub. No.: US 2009/0173967 A1
(43) Pub. Date: Jul. 9, 2009

(54) STRAINED-CHANNEL FET COMPRISING TWIST-BONDED SEMICONDUCTOR LAYER

(75) Inventors: Masafumi Hamaguchi, White Plains, NY (US); Ryoji Hasumi, Crompond, NY (US); Haizhou Yin, Poughkeepsie, NY (US); Katherine L. Saenger, Ossining, NY (US)

Correspondence Address: SCULLY, SCOTT, MURPHY & PRESSER, P.C., 400 GARDEN CITY PLAZA, SUITE 300, GARDEN CITY, NY, 11530, US

(73) Assignees: INTERNATIONAL BUSINESS MACHINES CORPORATION, Armonk, NY (US); TOSHIBA AMERICA ELECTRONIC COMPONENTS, INC., Irvine, CA (US)

(21) Appl. No.: 11/969,618

(22) Filed: Jan. 4, 2008

(51) Int. Cl. H01L 29/04; H01L 21/20; H01L 21/8238; H01L 27/092; H01L 29/778

(52) U.S. Cl. 257/190; 438/198; 438/199; 438/479; 257/255; 257/E29.004; 257/E21.09; 257/E21.632; 257/E27.062; 257/E29.246

(57) ABSTRACT

This invention provides a strained-channel field effect transistor (FET) in which the semiconductor of the channel of the FET is formed in a compliant substrate layer disposed over a twist-bonded semiconductor interface. This FET geometry increases the efficacy of local stress elements such as stress liners and embedded lattice-mismatched source/drain regions by mechanically decoupling the semiconductor of the channel region from the underlying rigid substrate. These strained-channel FETs may be incorporated into complementary metal oxide semiconductor (CMOS) circuits in various combinations. In one embodiment of this invention, both pFETs and nFETs are in a twist-bonded (001) silicon layer on a (001) silicon base layer. In another embodiment, pFETs are in a twist-bonded (011) silicon layer on a (001) silicon base layer and nFETs are in a conventional, non-twist-bonded (001) silicon base layer. This invention also provides a twist-bonded semiconductor layer on a polycrystalline base layer, as well as methods for fabricating the aforementioned FETs.

### FIELD OF THE INVENTION

This invention generally relates to field effect transistors (FETs) in which at least some channel strain is induced by one or more local stress elements, such as, for example, stress liners and/or lattice-mismatched embedded source/drain regions. More particularly, this invention relates to increasing the effectiveness of such local stress elements by forming the FET channel region in a compliant semiconductor layer disposed over a twist-bonded semiconductor interface.

### BACKGROUND OF THE INVENTION

Historically, most performance improvements in semiconductor field effect transistors (FETs) have been achieved by scaling down the relative dimensions of the device. This trend is becoming increasingly more difficult to maintain as the devices reach their physical scaling limits. As a consequence, advanced FETs and the complementary metal oxide semiconductor (CMOS) circuits in which they can be found are increasingly utilizing strain engineering to achieve desired circuit performance.

Strain engineering relies on the fact that carrier mobility may be increased by inducing strain in the semiconductor channel. The predicted mobility enhancements depend on the carrier type (holes or electrons), the magnitude of the applied stress, and direction of the applied stress in relation to the semiconductor crystal orientation and direction of current flow. In (001) silicon, for example, electron mobility is typically increased by tensile strain in the current flow direction (resulting in improved n-channel FET or nFET performance), while hole mobility is typically increased by compressive strain in the current flow direction (resulting in improved p-channel FET or pFET performance).

Substantial channel strain can be induced by local stress elements introduced during semiconductor device processing. Stress liner layers and lattice-mismatched embedded source/drain (S/D) regions are among the most useful and cost-effective of these local stress elements, and are incorporated into FETs 10 and 10 of FIG. 1. FETs 10 and 10′ comprise semiconductor layer or substrate 20 containing doped semiconductor source and drain (S/D) regions 30 and 30′ shown in lattice-mismatched embedded semiconductor regions 35 and 35′ Doped semiconductor S/D regions 30 and 30′ are separated by semiconductor channels 40 and 40′ disposed under gate dielectrics 50 and sot and conductive gates 60 and 60′. FETs 10 and 10′ are optionally separated by dielectric isolation regions 70. Gates 60 and 60′ are typically bordered with one or more dielectric sidewall spacers 80 (typically an inner oxide spacer that abuts at least the conductive gates and an outer nitride spacer that abuts the inner oxide spacer). Stress liner layers 90 and 90′ (typically a tensile or compressive silicon nitride) cover S/D regions 30 and 30′, dielectric sidewall spacers 80 and 80′, and conductive gates 60 and 60′. Stress liners 90 and 90′ may be formed from the same or different materials which may have the same or different stresses. When FETs 10 and 10′ are both nFETs or both pFETs, stress liners 90 and 90′ would typically be formed from the same material; when FETs 10 and 10′ comprise one nFET and one pFET, stress liners 90 and 90′ would typically be formed from a compressive material for the pFET and a tensile material for the nFET. Lattice-mismatched embedded semiconductor regions 35 and 35′ may be utilized for none, one, or both of FETs 10 and 10′, but would typically comprise SiGe alloys for pFETs and SiC alloys for nFETs for the case in which the surrounding semiconductor material (channels 40 and 40′ and semiconductor layer 30) was Si.

Unfortunately, the amount of channel strain that can induced by a stress liner 90 and 90′ is limited by the fact that the semiconductor of the channel region 40 and 40′ is part of (or tightly bound to) a rigid substrate (20). Channel strain could, in principle, be very substantially increased if one could find device geometries in which the semiconductor, in which the channel is disposed, is more compliant than a conventional rigid substrate, and therefore more responsive to locally applied stress elements.

### SUMMARY OF THE INVENTION

In view of the drawbacks mentioned above, the present invention provides a strained-channel FET in which the semiconductor channel of the FET is formed in a compliant substrate layer.

The present invention also provides a strained-channel FET in which the semiconductor channel of the FET is formed in a compliant substrate layer wherein the compliant substrate layer is only weakly bound to an underlying substrate and strained by at least one locally applied stress element such as, for example, stress liners, embedded lattice-mismatched S/D regions, etc. By “weakly bound”, it is meant that the connection between the compliant substrate layer and the underlying substrate is weak enough to allow a lateral shifting of the compliant layer with respect to the underlying substrate.

The present invention further provides semiconductor integrated circuits comprising a plurality of FETs wherein at least one of the FETs comprises a semiconductor channel formed in a compliant substrate layer strained by locally applied stress elements.

The present invention even further provides a complementary metal oxide semiconductor (CMOS) circuit comprising a plurality of nFETs and pFETs wherein at least one of the nFETs and pFETs comprises a semiconductor channel formed in a compliant substrate layer strained by locally applied stress elements.

The above-mentioned semiconductor structures may be achieved with a FET geometry in which the semiconductor channel of the FET is disposed (i.e., located) in a twist-bonded semiconductor layer having the properties of a compliant substrate, namely an elasticity and deformability in response to applied stress qualitatively similar to what one might expect in a freestanding thin film. It is also noted that the term “twist-bonded semiconductor layer” is used throughout this application to denote a semiconductor layer that is bonded to an underlying semiconductor layer in a manner that leaves an imperfect alignment of the crystal lattice sites on each side of the bonded interface.

In this invention, the properties of the twist-bonded semiconductor layer are exploited in a new way. Previously the deformation of the twist-bonded semiconductor layer in response to the stress of an epitaxially-grown, lattice-mismatched semiconductor overlayer was used to provide a benefit for the overlayer (i.e., a higher critical thickness). In the present invention, the deformation of the twist-bonded semiconductor layer in response to one or more locally applied stress elements is used to improve the properties of the twist-bonded semiconductor layer itself (i.e., to provide a higher carrier mobility). While the same stress elements will also cause a deformation (and mobility enhancement) in a conventional, non-twist-bonded semiconductor layer, the twist-bonded semiconductor layer is freer to deform and more responsive to locally applied stress elements. The thinner the twist-bonded semiconductor layer, the more easily it is deformed. From the point of view of maximizing strain sensitivity, the twist-bonded semiconductor layers of this invention are preferably thinner than 200 nm, more preferably thinner than 100 nm, and most preferably thinner than 50 nm. However, as will be discussed later, there are several process and design factors that should also be considered when selecting the thickness of the twist-bonded semiconductor layer.

In a first embodiment of the invention, an FET is provided that comprises a strained semiconductor channel disposed (i.e., located) in a twist-bonded semiconductor layer. A twist-bonded interface separates the twist-bonded semiconductor layer from an underlying substrate semiconductor layer. The semiconductor channel is situated between spaced-apart source and drain (S/D) regions and under a gate stack comprising a conductive gate disposed on a gate dielectric. At least some channel strain is induced by one or more local stress elements known to those skilled in the art, such as, for example, stress liner layers extending over the S/D regions and optionally over some part of the gate, embedded lattice-mismatched S/D regions, and/or a gate or gate stack with high intrinsic stress.

The twist-bonded semiconductor layer and the underlying substrate semiconductor layer may be selected from single crystal Si or Si-based materials such as, for example, SiC alloys, SiGe alloys, SiGeC alloys; Ge; various III-V materials such as GaAs; as well as layered or embedded combinations of these materials. The underlying substrate semiconductor layer may be a bulk substrate or a semiconductor-on-insulator layer. The twist-bonded semiconductor layer and the underlying substrate may be formed from the same material or from different materials, and they may have the same surface orientation or different surface orientations. For example, both the twist-bonded semiconductor layer and underlying substrate layer might both be Si with a (001) surface orientation, or they might both be Si, but with a (001) surface orientation for the underlying substrate layer and a (011) surface orientation for the twist-bonded semiconductor layer.

In a second embodiment of the invention, a plurality of FETs is provided wherein at least one of the FETs has a strained semiconductor channel disposed (i.e., located) in a twist-bonded semiconductor layer. In one variation of this embodiment of the present invention, the channels of both nFETs and pFETs would be in a (001) Si layer twist-bonded to an underlying (001) Si layer, with, for example, the FETs aligned with the in-plane <110> directions of the twist-bonded semiconductor layer and the in-plane <100> directions of the underlying semiconductor layer. In another variation of this embodiment of the present invention, nFETs would be in a non-twist-bonded (001) Si layer, and pFETs would be in a (011) Si layer twist-bonded to an underlying (001) Si substrate layer.

Another aspect of the invention relates to methods for fabricating strained-channel FETs comprising twist-bonded semiconductor layers. An exemplary method for forming one or more FETs on a twist-bonded semiconductor layer comprises forming a twist-bonded semicondcutor layer on a base semiconductor layer, and performing CMOS processing steps known to the one skilled in the art to form the one or more FETs, said CMOS processing steps including steps needed to provide the desired local stress elements.

Typically the desired local stress elements would be tailored according to whether the FET was an nFET or a pFET, since carrier mobility response to stress depends on type of carrier (hole or electron). nFET performance is generally enhanced with tensile stress liners and embedded lattice-mismatched S/D regions having a smaller lattice constant than the material of the channel (e.g., embedded SiC S/D regions for a Si channel), while pFET performance is generally enhanced with compressive stress liners and embedded lattice-mismatched S/D regions having a larger lattice constant than the material of the channel (e.g., embedded SiGe S/D regions for a Si channel).

Yet another aspect of the invention comprises a method of forming a twist-bonded semiconductor layer on a semiconductor-on-insulator layer without the expense of a conventional SOI wafer. In this method, the single-crystal SOI base semiconductor layer is replaced with a layer of polycrystalline semiconductor on an oxide-coated substrate. Twist-bonded semiconductor layers resulting from this procedure might be expected to have much the same properties to twist-bonded semiconductor layers formed on the conventional single-crystal substrate layers, and FETs having strained channels formed in such novel twist-bonded semiconductor layers are also taught by this invention.

### BRIEF DESCRIPTION OF THE DRAWINGS

These and other features, objects, and advantages of the present invention will become apparent upon a consideration of the following detailed description of the invention when read in conjunction with the drawings, in which:

FIG. 1 shows a cross section view of two prior art FETs incorporating various local stress elements;

FIGS. 2A-2J show a combination top view and cross section view of a conventional method for forming a twist-bonded silicon layer which can be used in the present invention;

FIGS. 3A-3D show cross section views of some preferred embodiments of the FETs of this invention, each FET including one or more local stress elements;

FIG. 4 shows a cross section view of a first preferred embodiment of this invention as applied to a plurality of FETs including at least one nFET and at least one pFET;

FIG. 5 shows a cross section view of a second preferred embodiment of this invention as applied to a plurality of FETs including at least one nFET and at least one pFET;

FIGS. 6A-6D show in cross section view the steps of a method of the present invention to form a twist-bonded semiconductor layer on a polycrystalline base semiconductor layer; and

FIGS. 7A-7B compare cross section views of strained-channel FETs on twist-bonded semiconductor layers disposed on a conventional, single crystal SOI base semiconductor layer (FIG. 7A), or on a polycrystalline SOI base semiconductor layer (FIG. 7B).

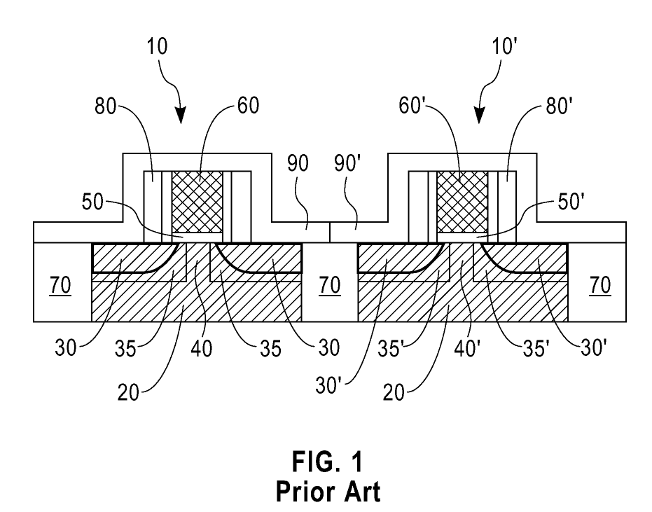

### DETAILED DESCRIPTION OF THE INVENTION

The present invention, which provides a semiconductor structure including at least one FET including a strained semiconductor channel disposed in a twist-bonded semiconductor layer in which at least some channel strain is induced by one or more local stress elements known in the art and related methods of forming the same, will now be described in greater detail by referring to the following discussion and drawings that accompany the present application. It is noted that the drawings of the present application are provided for illustrative purposes only and, as such, the drawings are not drawn to scale.

In the following description, numerous specific details are set forth, such as particular structures, components, materials, dimensions, processing steps and techniques, in order to provide a thorough understanding of the present invention. However, it will be appreciated by one of ordinary skill in the art that the invention may be practiced without these specific details. In other instances, well-known structures or processing steps have not been described in detail in order to avoid obscuring the invention.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

As stated above, the present invention provides a semiconductor structure including at least one FET comprising a strained semiconductor channel disposed in a twist-bonded semiconductor layer. In the inventive structure, at least some channel strain is induced by one or more local stress elements known to the art.

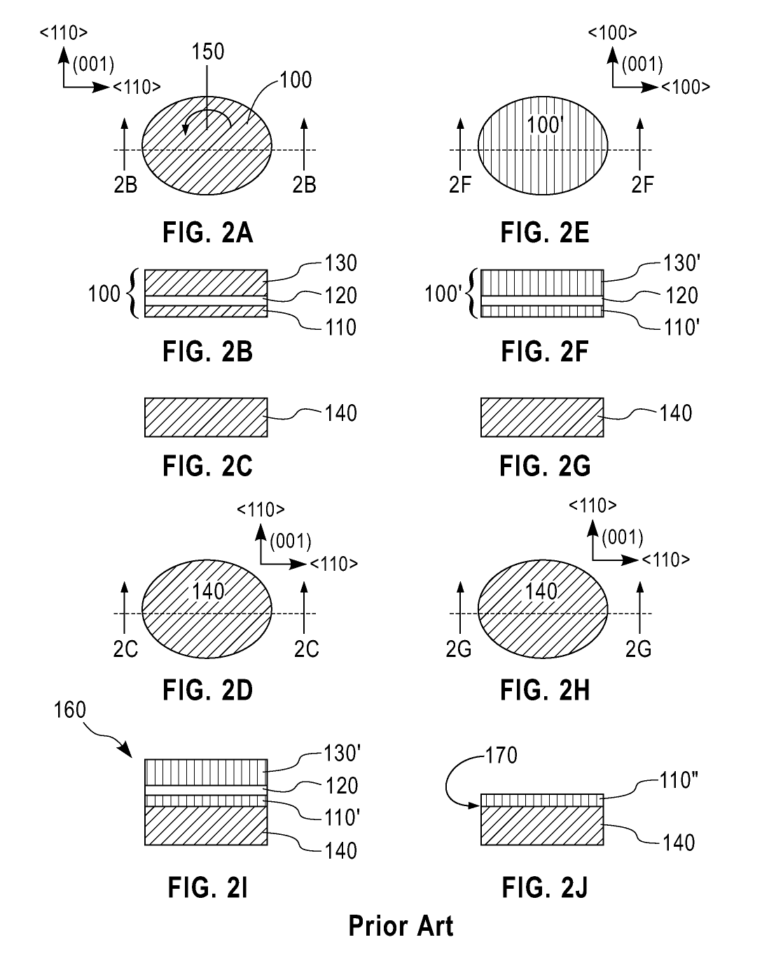

Before discussing the invention in greater detail, a general discussion of a method of forming a twist-bonded silicon layer is now provided. It is noted that although this method of forming a twist-bonded silicon layer is known in the art, it is one method that can be employed in the present invention in forming a twist-bonded silicon layer. FIGS. 2A-2J show top and cross section views of an exemplary prior art method for forming a twist-bonded silicon layer for the case in which both the twist-bonded silicon layer and the Si base substrate have the same (001) surface crystal orientation.

It should be noted that the notation (jkl) indicates a family of crystal planes with Miller indices j, k, and l, and that the notation <j′k′l′> indicates a family of equivalent directions with Miller indices j′, k′, and 1′. Here, and in the remainder of this application, the “in-plane <j′k′l′> direction” of a crystal having a (jkl) surface orientation should be taken as referring to <j′k′l′> directions which are coplanar with the (jkl)-oriented crystal's surface.

Donor wafer 100 (shown top view in FIG. 2A and in cross section view in FIG. 2B through line 2B-2B) includes silicon-on-insulator (SOI) donor layer 110, buried insulator layer 120, and donor base substrate 130, which will be bonded to Si base layer 140 (shown top view in FIG. 2D and in cross section view in FIG. 2C through line 2C-2C). Si base layer 140 may be bulk Si or a silicon-on-insulator layer. FIGS. 2E-2H show the substrates of FIGS. 2A-2D after donor wafer 100 has been rotated around surface normal 150 to produce deliberately misaligned donor wafer 100′ with misaligned donor base substrate 130′ and misaligned donor SOI layer 110′. For example, misaligned Si layer 110′ might have its in-plane <110> direction oriented to be parallel to an in-plane <100> direction of Si base layer 140. FIG. 2I shows the layers of FIGS. 2E-2H in cross section after bonding to produce structure 160, and FIG. 2J shows structure 160 of FIG. 2I in cross section after removal of donor base substrate 1301 and buried insulator layer 120 to leave twist-bonded layer 110″, Si base layer 140, and twist-bonded interface 170 between them.

This twist bonding leaves (i) a periodically varying strain field in the semiconductor regions in the immediate vicinity of the twist-bonded interface, a feature useful for growing self-assembled arrays of nanodots that selectively grow in regions having a particular strain or lattice spacing, and (ii) a compliant substrate in the form of a weakly bonded semiconductor layer which is relatively free to elastically deform in response to the stress of an epitaxially-grown, lattice-mismatched semiconductor overlayer, a situation which allows relatively defect-free growth of highly lattice-mismatched layers. These applications typically require the twist-bonded semiconductor layer to be extremely thin, on the order of 10 nm, because (i) the strain field decays rapidly with distance away from the bonded interface (washing out the periodically varying strain fields needed on the nanodot growth surface), and (ii) thinner layers are easier to deform, i.e., more compliant (something especially important when one is trying to grow lattice-mismatched overlayers).

Some of the properties of twist-bonded semiconductor layers have been described, for example, by J. Eymery et al. in “Dislocation Networks Strain Fields Induced by Si Wafer Bonding” [Mat. Res. Soc. Symp. Proc. 673 6.9 (2001)] and in “Dislocation strain field in ultrathin bonded silicon wafers studied by grazing incidence x-ray diffraction” [Phys. Rev. B 65 165337 (2002)], and by F. E. Ejeckam et al. in “Lattice engineered compliant substrate for defect-free heteroepitaxial growth” [Appl. Phys. Lett. 70 1685 (1997)] and in “Dislocation-free InSb grown on GaAs compliant universal substrates” [Appl. Phys. Lett. 71 776 (1997)]. In addition to the simple case illustrated within FIGS. 2A-2J in which the twist bonding is between two Si layers having the same surface orientation, one may also form a twist-bonded semiconductor layer by bonding a semiconductor layer and a semiconductor base substrate having different surface orientations (e.g., a rotated Si (011) SOI layer bonded to a Si (001) base substrate), or by bonding semiconductor layers and base substrates that are not Si-based (e.g., a rotated GaAs layer bonded to a GaAs base substrate).

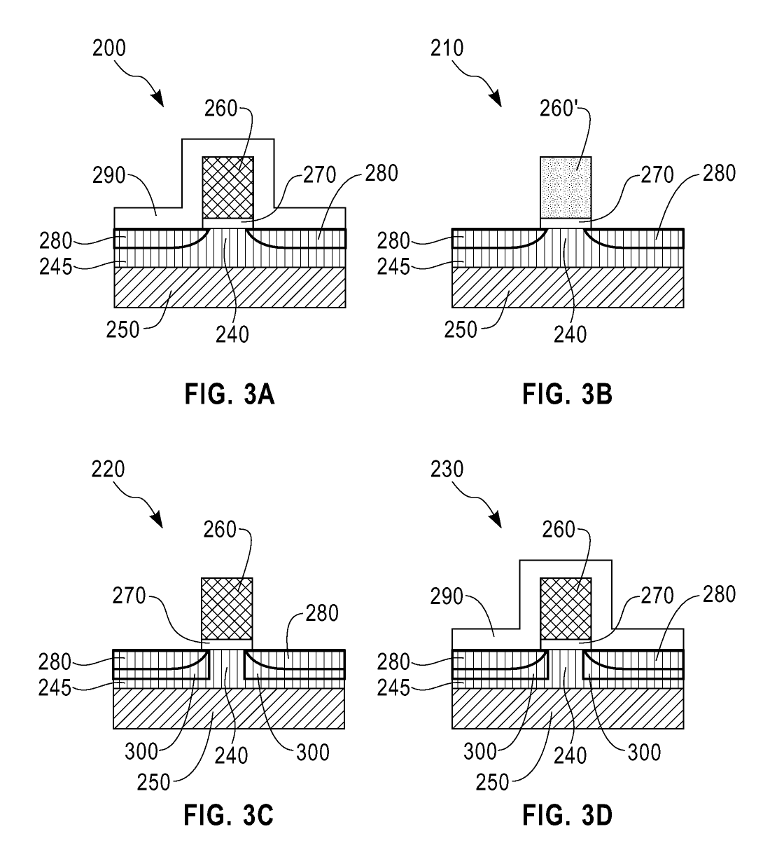

Given the above general discussion of how one can form a twist-bonded silicon layer, the present invention will now be described in more detail. Specifically, reference is made to FIGS. 3A-3D which show cross section views of four preferred embodiments of the FETs of this invention. FETs 200, 210, 220, and 230 each comprise a channel region 240 located in a twist-bonded semiconductor layer 245 disposed on a base semiconductor substrate 250, spaced-apart S/D regions 280, gate dielectric 270, and conductive gate 260 or 260′. Conductive gates 260 and 260′ may comprise single or multiple layers of one or more conductive materials, such as, for example, doped polycrystalline silicon, polycrystalline SiGe or Ge, conductive metal nitrides, metals, metal silicides, germanides, as well as mixtures and alloys of these materials. Conductive gates 260 and 260′ differ in that conductive gate 260′ of FIG. 3B has a high intrinsic stress (on the order of about 5 GPa or greater, for example) that imparts some strain to the underlying channel 260. Titanium nitride (TiN) is an example of a conductive gate material that can be prepared with high (5-10 GPa compressive) intrinsic stress. The FET of FIG. 3A has a stress liner 290 (typically an insulating material such as SiN), the FET of FIG. 3C has embedded lattice-mismatched S/D regions 300, and the FET of FIG. 3D has both a stress liner 290 and embedded lattice-mismatched S/D regions 300.

To maximize strain sensitivity, the twist-bonded semiconductor layers of this invention are preferably thinner than 200 nm, more preferably thinner than 100 nm, and most preferably thinner than 50 nm. A typical thickness range of the twist-bonded semiconductor layers employed in the present invention is from about 2 to about 100 nm. However, there are two other factors that should also be considered when selecting the twist-bonded layer thickness. First, as has been discussed in the context of hybrid orientation direct-silicon-bonded (DSB) pFETs, it is best if the twist-bonded interface does not fall within the depletion region of the device, since that location of the device appears to be correlated with higher well-to-S/D junction leakage [see, for example, H. Yin et al., “Scalability of Direct Silicon Bonded (DSB) Technology for 32 nm Node and Beyond,” VLSI Symp. p. 222 (2007)]. Second, the twist-bonded interface is susceptible to being “erased” if the device fabrication includes amorphizing S/D implants that extend below the twist-bonded interface, since these regions, which will be recrystallized by solid phase epitaxy (SPE) templated by the base substrate layer, lose their original orientation. While this would still leave a twist-bonded interface under the FET's channel, it would decrease the mechanical flexibility of the S/D regions, resulting in a reduced amount of channel strain. It is therefore preferable to adjust the thickness of the twist-bonded semiconductor layer and the depth of the S/D regions so that the twist-bonded semiconductor layer is thick enough to contain the entirety of the S/D regions without extending more than 10-100 nm below the bottom of the S/D regions.

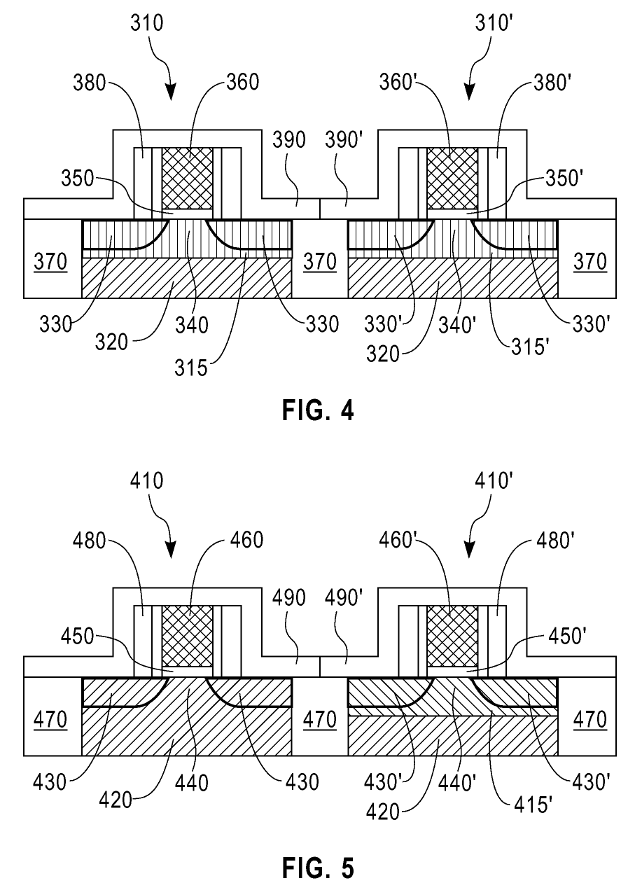

In a second embodiment of the invention, a plurality of FETs is provided wherein at least one of the FETs has a strained semiconductor channel disposed (i.e., located) in a twist-bonded semiconductor layer. In a first variation of this embodiment, at least one nFET and at least one pFET in a CMOS circuit have channels formed (i.e., located) in a twist-bonded semiconductor layer, as illustrated in the cross section view of FIG. 4. nFET 310 and pFET 310′ include twist-bonded semiconductor layer 315 disposed on base semiconductor layer or substrate 320 containing doped semiconductor S/D regions 330 and 330′ separated by semiconductor channels 340 and 340′ disposed under gate dielectrics 350 and 350′ and conductive gates 360 and 360′. FETs 310 and 310′ are optionally separated by dielectric isolation regions 370. Gates 360 and 360′ are typically bordered with one or more dielectric sidewall spacers 380 and 380′ (typically an inner oxide spacer and an outer nitride spacer). Stress liner layers 390 and 390′ cover S/D regions 330 and 330′, dielectric sidewall spacers 380 and 380′, and gates 360 and 360′. Stress liners 390 and 390′ would typically be formed from a tensile material for nFET 310 and from a compressive material for pFET 310′.

While the base semiconductor 320 and the twist-bonded semiconductor layer 340 and 340′ of FIG. 4 may have a variety of semiconductor materials, a variety of surface orientations, and be bonded at a variety of twist angles, a preferred arrangement would have twist-bonded semiconductor layer 315 and the underlying base semiconductor layer 320 comprise (001) Si, with, for example, FETs 310 and 310′ aligned with the in-plane <110> directions of twist-bonded semiconductor layer 315 and the in-plane <100> directions of underlying semiconductor layer 320. While the structure of FIG. 4 shows only a single local stress element (dual stress liner layers 390 and 390′), such structures would typically also include one or more lattice-mismatched embedded S/D regions, as well as any other local stress elements desired.

In a second variation of this embodiment, at least one FET in a CMOS circuit would have a channel in a non-twist-bonded semiconductor layer and at least one FET in a CMOS circuit would have a channel formed in a twist-bonded semiconductor layer. This is illustrated in the cross section view of FIG. 5 for the case of nFET 410 and pFET 410′. nFET 410, comprising non-twist-bonded semiconductor layer 420, and pFET 410′, comprising twist-bonded semiconductor layer 415 disposed on base semiconductor layer or substrate 420′, have doped semiconductor S/D regions 430 and 430′ separated by semiconductor channels 440 and 440′ disposed under gate dielectrics 450 and 450′ and conductive gates 460 and 460′. FETs 410 and 410′ are optionally separated by dielectric isolation regions 470. Gates 460 and 460′ are typically bordered with one or more dielectric sidewall spacers 480 (typically an inner oxide spacer and an outer nitride spacer). Stress liner layers 490 and 490′ cover S/D regions 430 and 430′, dielectric sidewall spacers 480 and 480′, and gates 460 and 460′. Stress liners 490 and 490′ would typically be formed from a tensile material for nFET 410 and from a compressive material for pFET 410′.

While base semiconductor 420′ and twist-bonded semiconductor layer 415 may have a variety of surface orientations and be bonded at a variety of twist angles, a preferred arrangement would have twist-bonded semiconductor layer 415 comprise Si with a (011) surface orientation, and base semiconductor layer 420′ (as well as non-twist-bonded semiconductor layer 420) comprise Si with a (001) orientation, with the in-plane <100> direction of the (011) twist-bonded semiconductor layer aligned to be parallel to the in-plane <100> direction of the underlying (001) Si, with the FETs aligned so that nFET and pFET current flow is along the in-plane <110> direction of the twist-bonded (011) semiconductor layer. While the structure of FIG. 5 shows only a single local stress element (dual stress liner layers 490 and 490′), such structures would typically also include one or more lattice-mismatched embedded S/D regions.

Another aspect of the invention relates to methods for fabricating strained-channel FETs comprising twist-bonded semiconductor layers, such as described above and illustrated within FIGS. 3-5. An exemplary method of the present invention for forming an FET on a twist-bonded semiconductor layer includes first forming a twist-bonded layer on a base semiconductor layer; and thereafter performing CMOS processing steps known to one skilled in the art to form said FET. The CMOS processing steps not only include FET device fabrication but also include steps needed to provide the desired local stress elements.

In this inventive method, the twist-bonded semiconductor layer and the underlying substrate semiconductor layer may be selected from single crystal Si or Si-based materials such as SiC alloys, SiGe alloys, SiGeC alloys; Ge; various III-V materials such as GaAs; as well as layered or embedded combinations of these materials. The underlying substrate semiconductor layer may be a bulk substrate or a semiconductor-on-insulator layer. The twist-bonded semiconductor layer and the underlying substrate may be formed from the same material or from different materials, and they may have the same surface orientation or different surface orientations.

An exemplary method of the present invention for forming a plurality of FETs including at least one nFET and at least one pFET, both on twist-bonded semiconductor layers includes first forming a twist-bonded semiconductor layer on a base semiconductor layer; and thereafter performing CMOS processing steps known to those skilled in the art to form nFETs and pFETs on the twist-bonded layer, said CMOS processing steps also including steps needed to provide the desired local stress elements.

An exemplary method of the present invention for forming a plurality of FETs including at least one nFET and at least one pFET, the nFET on a non-twist-bonded (001) Si layer and the pFET on a twist-bonded (011) Si layer includes forming a twist-bonded (011) Si layer on a (001) Si base substrate layer, said twist-bonded and base substrate layers separated by a twist-bonded interface; amorphizing selected areas of the (011) Si layer to a depth below the twist-bonded interface and recrystallizing said amorphized areas to the orientation of the base substrate layer to produce changed-orientation (001) Si regions and original-orientation, twist-bonded (011) Si regions; performing CMOS processing steps known to those skilled in the art to form nFETs on the changed-orientation (001) regions and pFETs on the original-orientation, twist-bonded (011) semiconductor regions, said CMOS processing steps including steps needed to provide the desired local stress elements. In this method of the present invention, the amorphizing step includes a conventional amorphization ion implantation process and the recrystallizing step includes a conventional annealing step that is capable of converting the amorphized region back to a crystalline region.

In the methods generally described above, said processing steps known to those skilled in the art for forming nFETs and pFETs should be taken to include both conventional “gate-first” integration schemes, in which the gate is in place before the S/D implants and activation anneals, and replacement or “gate last” integration schemes, in which a sacrificial dummy gate is removed and replaced after the S/D implants and activation anneals. These two process flows are discussed, for example, by H.-S. P. Wong in “Beyond the conventional transistor” [IBM Journal of Research and Development 46 133 (2002)].

Another aspect of the invention comprises a method of forming a twist-bonded semiconductor layer on a semiconductor-on-insulator layer without the expense of a conventional SOI wafer. In this method of the present invention, the single-crystal SOI base semiconductor layer is replaced with a layer of polycrystalline semiconductor on an oxide-coated substrate. The method to form this novel twist-bonded layer includes selecting a starting substrate (typically a Si wafer); forming an insulating layer on said substrate (typically a thermal oxide layer 10 to 2000 nm in thickness); forming a polycrystalline semiconductor layer (typically a polycrystalline Si or SiGe layer 2-100 nm in thickness and more preferably 5-50 nm in thickness) on said insulating layer and optionally performing a grain growth anneal and/or a surface polish step; bonding a single crystal semiconductor layer directly to said polycrystalline layer to form a twist-bonded layer on a twist-bonded interface.

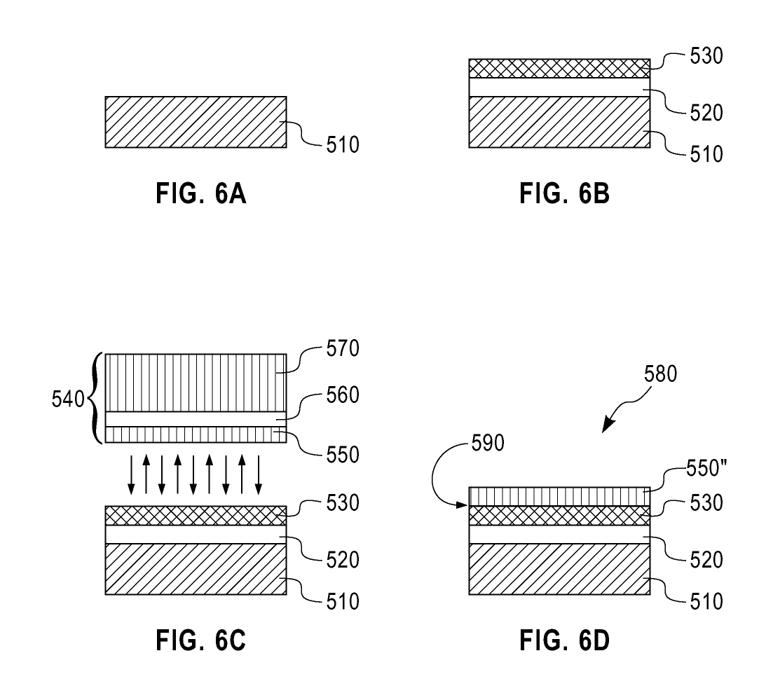

The steps of this method of the present invention are shown in FIGS. 6A-6D in cross section view. FIG. 6A shows base silicon wafer 510, and FIG. 6B shows base silicon wafer 510 after formation of insulator layer 520 and polycrystalline semiconductor layer 530. Polycrystalline semiconductor layer 530 would typically be selected from the same group of materials as previously mentioned as possibilities for crystalline semiconductor base layers, and may be formed by any deposition method known to the art, including, for example, low pressure chemical vapor deposition. Donor wafer 540 comprising silicon-on-insulator (SOI) donor layer 550, buried insulator layer 560, and donor base substrate 570, is bonded to polycrystalline layer 530, as shown in FIG. 6C. The bonding is performed utilizing a conventional wafer bonding process known to those skilled in the art. After bonding, donor base substrate 570 and buried insulator layer 560 are removed to leave structure 580 with twist-bonded layer 550″ on polycrystalline semiconductor layer 530 with twist-bonded interface 590 between them.

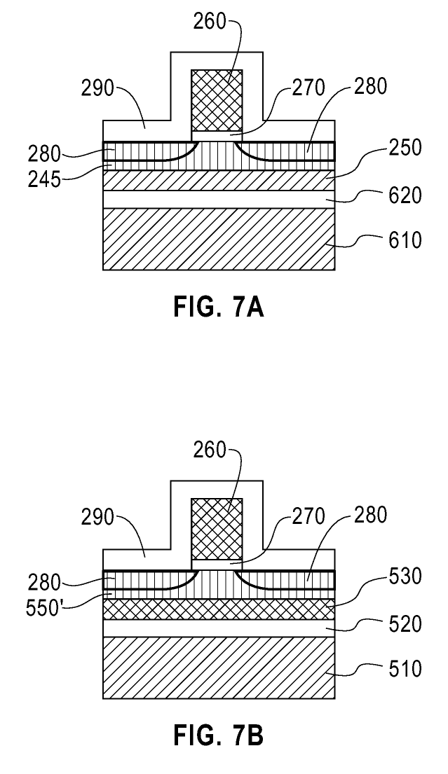

Twist-bonded layers resulting from this procedure might be expected to have much the same properties to twist-bonded layers formed on the conventional single-crystal substrate underlayers. FIGS. 7A and 7B compare cross section views of strained-channel FETs on twist-bonded semiconductor layers disposed on a conventional SOI base semiconductor layer (FIG. 7A), or the polycrystalline SOI base semiconductor layer just described (FIG. 7B). The FETs of FIGS. 7A and 7B share similar base substrates 610 and 510, buried insulator layers 620 and 520, twist-bonded layers 245 or 530, conductive gates 260, gate dielectrics 270, and stress liner layers 290. However the base semiconductor layer comprises single crystalline material 250 in FIG. 7A and polycrystalline semiconductor material 550′ in FIG. 7B. Like the FETs of FIGS. 3A-3D, FIG. 4, and FIG. 5, the FET of FIG. 7B may include local stress elements in addition to, or instead of, those shown.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

What is claimed is:

1. A field effect transistor (FET) comprising a strained semiconductor channel located in a twist-bonded semiconductor layer and situated between spaced-apart source/drain (S/D) regions and under a gate stack, wherein a twist-bonded interface separates the twist-bonded semiconductor layer from an underlying substrate semiconductor layer, and at least some channel strain is induced by one or more local stress elements.

2. The FET of claim 1 wherein said one or more local stress elements are selected from the group including stress liner layers extending over the S/D regions and optionally extending over some part of the gate stack, embedded lattice-mismatched S/D regions, and a gate or gate stack with high intrinsic stress.

3. The FET of claim 1 wherein said twist-bonded semiconductor layer has a thickness from about 2 nm to about 100 nm.

4. The FET of claim 1 wherein the twist-bonded semiconductor layer comprises a material selected from single crystal Si, Si-based materials, Ge, III-V materials, and layered or embedded combinations of these materials.

5. The FET of claim 1 wherein the underlying substrate semiconductor layer comprises a material selected from single crystal Si, polycrystalline Si, Si-based materials, Ge, III-V materials, and layered or embedded combinations of these materials.

6. The FET of claim 1 wherein said underlying substrate semiconductor layer is a bulk semiconductor substrate or a semiconductor-on-insulator layer.

7. A semiconductor structure comprising a plurality of field effect transistors (FETs) each including at least a gate stack and S/D regions located on a substrate, wherein at least one of the FETs has a strained semiconductor channel disposed in a twist-bonded semiconductor layer located atop said substrate and at least some channel strain is induced by one or more local stress elements.

8. The semiconductor structure of claim 7 wherein said one or more local stress elements are selected from the group including stress liner layers extending over the S/D regions and optionally extending over some part of the gate stack, embedded lattice-mismatched S/D regions, and a gate or gate stack with high intrinsic stress.

9. The semiconductor structure of claim 7 wherein some of said plurality of FETs comprise at least one nFET and others of said plurality of FETs comprise at least one pFET both of which have channels in a (001) Si layer twist-bonded to an underling (001) Si layer.

10. The semiconductor structure of claim 7 wherein some of said plurality of FETs comprise at least one nFET in a non-twist-bonded (001) Si layer, and others of said plurality of FETs comprise at least one pFET in a (011) Si layer twist-bonded to an underlying (001) Si substrate layer.

11. A method for forming at least one field effect transistor (FET) on a twist-bonded semiconductor layer comprising:
forming a twist-bonded semiconductor layer on a base semiconductor layer; and
forming at least one FET on said twist-bonded semiconductor layer, wherein said forming said at least one FET includes forming at least one local stress element adjacent said at least one FET.

12. The method of claim 11 wherein said at least one local stress element is selected from the group including stress liner layers extending over S/D regions of said at least one FET and optionally extending over some part of a gate stack of said at least one FET, embedded lattice-mismatched S/D regions, and a gate or gate stack with high intrinsic stress.

13. The method of claim 11 wherein said twist-bonded semiconductor layer has a thickness from about 2 nm to about 100 nm.

14. The method of claim 11 wherein the twist-bonded semiconductor layer comprises a material selected from single crystal Si, Si-based materials, Ge, III-V materials, and layered or embedded combinations of these materials.

15. The method of claim 11 wherein the based semiconductor layer comprises a material selected from single crystal Si, polycrystalline Si, Ge, Si-based materials, III-V materials, and layered or embedded combinations of these materials.

16. The method of claim 11 wherein said base semiconductor layer is a bulk semiconductor substrate or a semiconductor-on-insulator layer.

17. The method of claim 11 wherein said at least one FET includes at least one nFET and at least one pFET, both of which are located on twist-bonded semiconductor layers.

18. A method for forming a plurality of FETs including at least one nFET and at least one pFET, the nFET on a non-twist-bonded (001) Si layer and the pFET on a twist-bonded (011) Si layer comprising:
forming a twist-bonded (011) Si layer on a (001) Si base substrate layer, said twist-bonded and base Si substrate layers separated by a twist-bonded interface;
amorphizing selected areas of the (011) Si layer to a depth below the twist-bonded interface and recrystallizing said amorphized areas to the orientation of the Si base substrate layer to produce changed-orientation (001) Si regions and original-orientation, twist-bonded (011) Si regions; and
forming at least one nFET on the changed-orientation (001) regions and at least one pFET on the original-orientation, twist-bonded (011) regions, said forming the at least one nFET and the at least one pFET including formation of at least one local stress element.

19. The method of claim 18 wherein said at least one local stress element is selected from the group including stress liner layers extending over S/D regions of said at least one nFET and said at least one pFET, and optionally extending over some part of a gate stack of said at least one nFET and said at least one pFET, embedded lattice-mismatched S/D regions, and a gate or gate stack with high intrinsic stress.

20. A method of forming a twist-bonded semiconductor layer on a semiconductor-on-insulator layer comprising:
selecting a starting substrate;
forming an insulating layer on said substrate;
forming a polycrystalline semiconductor layer on said insulating layer; and
bonding a single crystal semiconductor layer directly to said polycrystalline layer to form a twist-bonded layer on a twist-bonded interface.
